(19) United States
(12) Patent Application Publication
(10) Pub. No.: US 2015/0351229 A1
(43) Pub. Date: Dec. 3, 2015

(54) PRINTED CIRCUIT BOARD COMPRISING CO-PLANAR SURFACE PADS AND INSULATING DIELECTRIC

(71) Applicant: Avago Technologies General IP (Singapore) Pte. Ltd, Singapore (SG)

(72) Inventors: Lea-Teng Lee, Sunnyvale, CA (US); Sarah Haney, San Jose, CA (US)

(73) Assignee: Avago Technologies General IP (Singapore) Pte. Ltd, Singapore (SG)

(21) Appl. No.: 14/289,098

(22) Filed: May 28, 2014

(51) Int. Cl. H05K 1/02; H05K 3/06; H05K 1/09

(52) U.S. Cl. CPC H05K 1/0268; H05K 1/092; H05K 3/064; H05K 3/06

(57) ABSTRACT

A printed circuit board (PCB) comprises a non-conductive base layer, a conductive interconnect disposed on the non-conductive base layer and comprising at least two surface pads separated by a trench, and a insulating dam disposed in the trench, wherein the insulating dam electrically isolates the at least two surface pads and has an upper surface that is substantially co-planar with respective upper surfaces of the at least two surface pads.

### BACKGROUND

A printed circuit board (PCB) is a structure designed to mechanically support and electrically connect electronic components. A typical PCB comprises a non-conductive base layer and a conductive interconnect layer disposed on the base layer. The interconnect layer forms electrical paths that allow communication between electronic components mounted on the PCB. These electrical paths are typically formed by attaching a conductive material such as copper onto the base layer, and then etching the conductive material. The PCB may further comprise additional non-conductive layers and interconnect layers stacked in a multi-layer structure. Such a multi-layer structure may also include embedded circuit components such as capacitors, inductors, resistors, and so on.

A PCB may be connected with electronic components in a variety of different ways, with two common examples being through-hole technology and surface mount technology (SMT). With through-hole technology, electronic components are connected to a PCB by inserting wire leads on the components into via holes in the PCB surface. With SMT, on the other hand, electronic components are attached directly to a surface of an outer layer of the PCB, for example, using packages with external ball grid arrays (BGAs), land grid arrays (LGAs), and so on.

When attaching an electrical component to a PCB, it is important to maintain electrical isolation between adjacent connections. For instance, when a BGA is soldered onto a PCB, it is important to ensure that solder balls of adjacent connections are not mistakenly connected to the same surface pad on the PCB. One way to maintain such isolation is through the use of a solder mask, which comprises a non-conductive material disposed on top of an outer interconnect layer of a PCB and having openings through which surface pads of the PCB can be connected to electronic components.

FIG. 1 is a cross-sectional view of a conventional PCB 100 comprising a solder mask. As illustrated in FIG. 1, PCB 100 comprises a base layer 105, an interconnect 110, and a solder mask 115. Base layer 105 can be formed by any of various conventional materials, such as pre-preg, PTFE, PVC, and so on. Interconnect 110 can be formed by copper or another suitable conductive material. Solder mask 115 can be formed of an epoxy liquid, photoimageable solder mask (LPSM) ink, or a dry film photoimageable solder mask (DFSM), for example.

Interconnect 110 is typically formed by disposing a conductive layer on base layer 105 by lamination, although it could be placed there by other techniques known to those skilled in the art. The conductive material is then patterned to form electrical paths constituting interconnect 110. As an alternative to lamination and patterning, which is a subtractive technique, interconnect 110 could also be formed by additive or semi-additive processes known to those skilled in the art.

After interconnect 110 is formed on base layer 105, solder mask 115 is formed by depositing a layer of non-conductive material over interconnect 110, and then patterning the non-conductive material, typically by photolithography. This results in a structure in which some portions of solder mask 115 are disposed in trenches between adjacent tracks of interconnect 110, some portions of solder mask 115 are disposed above interconnect 110, and surface pads of interconnect 110 are exposed through openings in solder mask 115.

Conventional PCBs, such as that illustrated in FIG. 1, suffer from a variety of shortcomings that may become increasingly problematic as the PCB feature size is decreased to accommodate smaller packages. First, the topography of the solder mask, including its extension over the surface pads, adds to the complexity of testing, as probe lengths must be sufficient to contact the surface pads through the solder mask. Second, the topography of the solder mask may also fragilize the PCB with respect physical stresses such as those produced by bending, drop testing, or other mechanical phenomena.

In view of these and other shortcomings of conventional PCBs, there is a general need for improved PCBs providing more convenient access to surface pads for probing while maintaining adequate and reliable surface pad isolation and resistance to physical stresses.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a cross-sectional view of a conventional PCB comprising a solder mask.

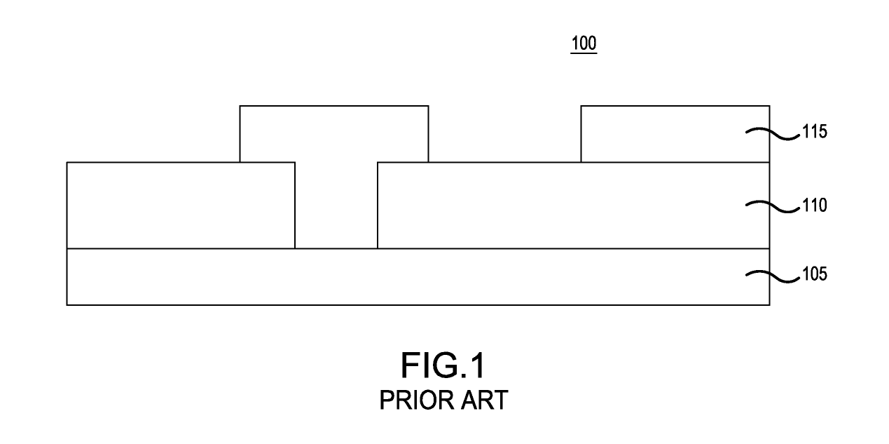

FIG. 2 is a cross-sectional view of a PCB comprising a solder mask and surface pads having substantially co-planar upper surfaces, according to a representative embodiment.

FIG. 3A is a cross-sectional view of an intermediate structure formed during the manufacture of a PCB according to a representative embodiment.

FIG. 3B is a cross-sectional view of another intermediate structure formed during the manufacture of a PCB according to a representative embodiment.

FIG. 3C is a cross-sectional view of another intermediate structure formed during the manufacture of a PCB according to a representative embodiment.

FIG. 3D is a cross-sectional view of a PCB comprising a solder mask and surface pads having substantially co-planar upper surfaces, according to a representative embodiment.

FIG. 4 is a flowchart illustrating a method of manufacturing a PCB comprising a solder mask and surface pads having substantially co-planar upper surfaces, according to a representative embodiment.

FIG. 5 is a scanning electron microscope (SEM) image of a PCB comprising a solder mask and surface pads having substantially co-planar upper surfaces, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms ‘a’, ‘an’ and ‘the’ include both singular and plural referents, unless the context clearly dictates otherwise. Thus, for example, ‘a device’ includes one device and plural devices. The terms ‘substantial’ or ‘substantially’ mean to within acceptable limits or degree. The term ‘approximately’ means to within an acceptable limit or amount to one of ordinary skill in the art. Relative terms, such as “above,” “below,” “to,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

The disclosed embodiments relate generally to PCBs and related methods of manufacture. In certain embodiments, a solder mask is applied to a PCB and patterned after pad plating. The solder mask may be designed to fill a trench between surface pads without contacting sides of the surface pads. Additionally, the solder mask may be formed with an upper surface that is substantially co-planar with an upper surface of the surface pads. Both liquid and dry film solder resist may be used to form the solder mask, although certain embodiments will be described with respect to the dry film solder resist.

In certain embodiments, a PCB is manufactured by defining copper pads using dry film resist, etching and the stripping the dry film resist to form the surface pads with appropriate surface finish, performing surface cleaning and adhesion promotion steps on the surface pads, and then applying and patterning dry film or liquid solder resist to isolate the surface pads.

In certain embodiments, a PCB comprises at least two surface pads separated by a trench, and a solder mask disposed in the trench, wherein the solder mask electrically isolates the at least two surface pads and has an upper surface that is substantially co-planar with respective upper surfaces of the at least two surface pads. Such a PCB can be manufactured by, e.g., patterning a metal layer using a mask to produce at least two surface pads separated by a trench, removing the mask, applying a layer of solder resist over plurality of surface pads and within the trench, and patterning the layer of solder resist to produce a solder mask within the trench, wherein the solder mask electrically isolates the at least two surface pads and has an upper surface that is substantially co-planar with respective upper surfaces of the at least two surface pads.

The use of a solder mask that is substantially co-planar with surface pads may provide a desired level of electrical isolation between the surface pads while avoiding obstruction of testing probes and improving resistance to physical stresses. It may also improve mold flow for low standoff devices while maintaining solder stop properties. Moreover, as solder volumes reduce, it may aid solder attachment of a package during assembly.

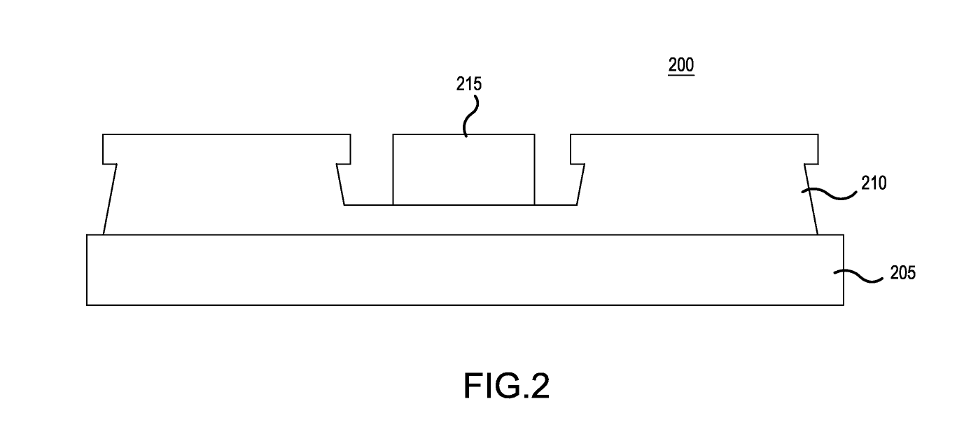

FIG. 2 is a cross-sectional view of a PCB 200 comprising a solder mask and surface pads having substantially co-planar upper surfaces, according to a representative embodiment.

Referring to FIG. 2, PCB 200 comprises abuse layer 205, an interconnect 210 comprising multiple surface pads separated by a trench, and a solder mask 215 having an upper surface that is substantially co-planar with upper surfaces of the surface pads comprising an insulating dielectric disposed in the trench without touching sides of the surface pads.

PCB 200 may further comprise additional layers stacked below base layer 205, such as additional base layers and interconnect layers. It may also include embedded electronic components within such a stacked structure, such as resistors, capacitors, etc. In general, base layer 205 and interconnect 210 as shown in FIG. 2 will reside at an external portion of PCB 200 to allow contact between the surface pads and electronic components. Although FIG. 2 shows surface pads on only one side of PCB 200, additional surface pads may be included on the other side of PCB 200.

Base layer 205 typically comprises pre-preg or another suitable non-conductive material, and interconnect 210 typically comprises copper or another suitable conductive material. Solder mask 115 can be formed of an epoxy liquid, LPSM ink, or a DFSM, for example. Although not shown in FIG. 2, PCB 200 may further include additional materials known to those skilled in the art. For example, it may include an adhesion promoting material for binding base layer 205 to interconnect 210.

In some embodiments, the surface pads of interconnect 210 may function as test pads of PCB 200. During a test procedure of PCB 200, a user may apply one or more test probes to the test pads and apply electrical signals to interconnect 210 through the test pads. Because solder mask 15 has an upper surface that is substantially co-planar with the surface pads, the surface pads may be more accessible to the test probes than those of conventional PCBs. In other words, they may allow the user to place the test probes in contact with the surface pads without obstruction from solder mask 215. Although the surface pads may generally be formed of copper, they may also comprise other materials, such as gold on copper, or gold on nickel on copper.

The various features of PCB 200 can be formed by a combination of steps, which individually may have been used previously in other contexts. For instance, the illustrated features may be formed by a combination of lamination, etching, exposures, planarization, and so on. Additionally, intervening steps, such as cleaning, adhesion preparation, and so on, may be performed in ways that would be apparent to those skilled in the art with the benefit of this description. Nevertheless, the unique order and/or combination in which these steps are performed may produce a structure unlike those of existing PCBs.

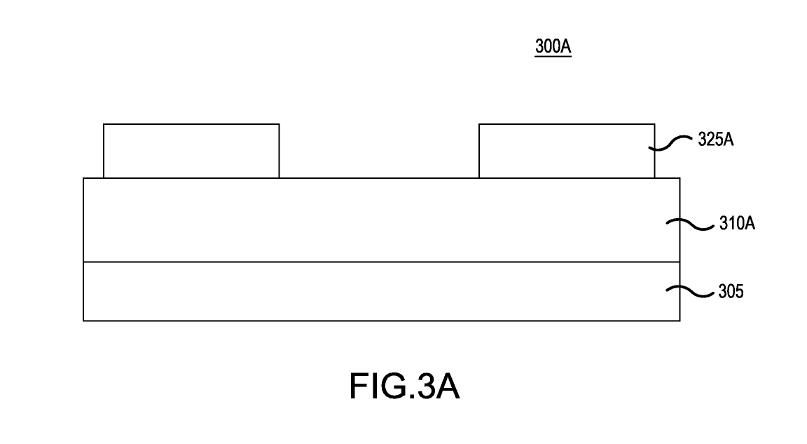

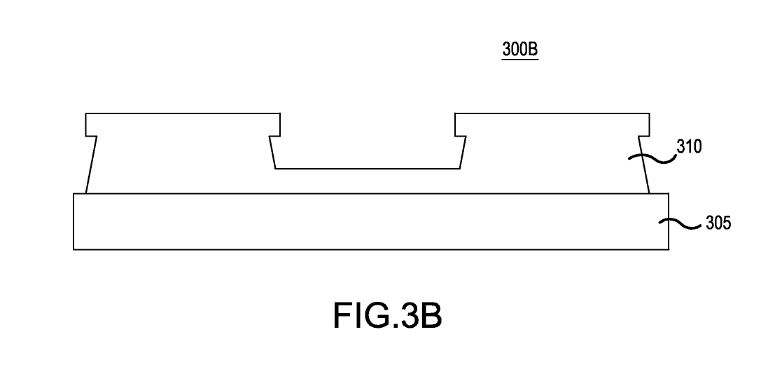

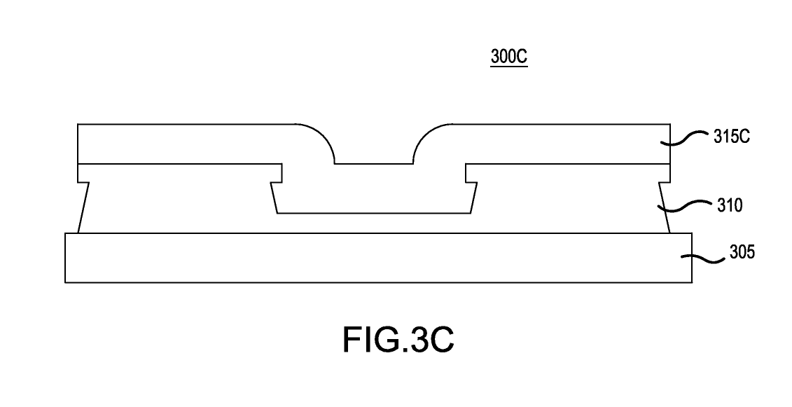

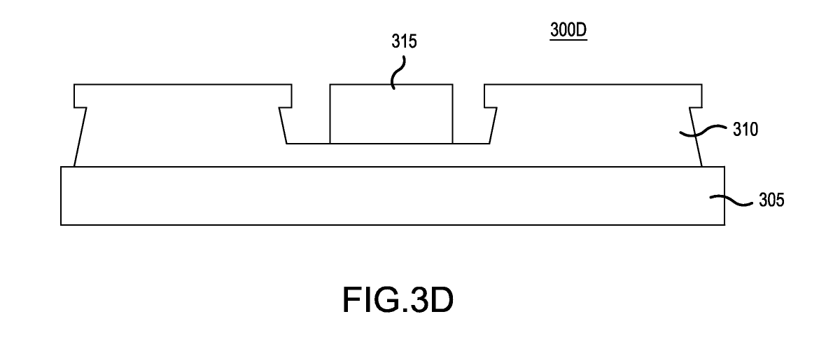

FIGS. 3A through 3D are cross-sectional views illustrating a method of manufacturing PCB 200 according to a representative embodiment. Each of these views includes an intermediate structure produced by one or more steps in the method. Although not shown in the drawings, additional structures may be produced by intervening, preceding, or succeeding steps as will be apparent to those skilled in the art with the benefit of this description.

Referring to FIG. 3A, a first intermediate structure 300A comprises a base layer 305, a conductive layer 310A attached to base layer 305, and a dry film resist layer 325A. Dry film resist layer 325A is formed on conductive layer 310A to define surface pads of an interconnect 310 to be formed subsequently. It serves as an etching mask in an etching process used to remove a portion of conductive layer 310A.

Referring to FIG. 3B, a second intermediate structure 300B comprises base layer 305 and an interconnect 310 having surface pads to be connected to an electronic device or a test probe, and a trench formed between the surface pads. Second intermediate structure 300B is formed by etching intermediate structure 300A using dry film resist layer 325A as an etching mask, and then stripping away dry film resist layer 325A. In addition to the etching and stripping, intermediate structure 300B may also undergo surface cleaning and adhesion promotion steps to complete the formation of the surface pads.

Referring to FIG. 3C, a third intermediate structure 300C comprises base layer 305, interconnect 310, and an insulating dielectric coating 315C, which is typically formed of a dry film or liquid solder resist. Insulating dielectric coating 315C can be formed on interconnect 310 of intermediate structure 300B by any of several techniques that would be apparent to those skilled in the art.

Referring to FIG. 3D, a fourth intermediate structure 300D comprises a solder mask 315, which is formed by patterning insulating dielectric coating 315C to isolate the surface pads of interconnect 310, and optionally planarizing an upper surface of the surface pads and solder mask 315 to ensure that their respective upper surfaces are substantially co-planar. Such planarization may comprise, for instance, a chemical mechanical planarization (CMP) or another form of planarization.

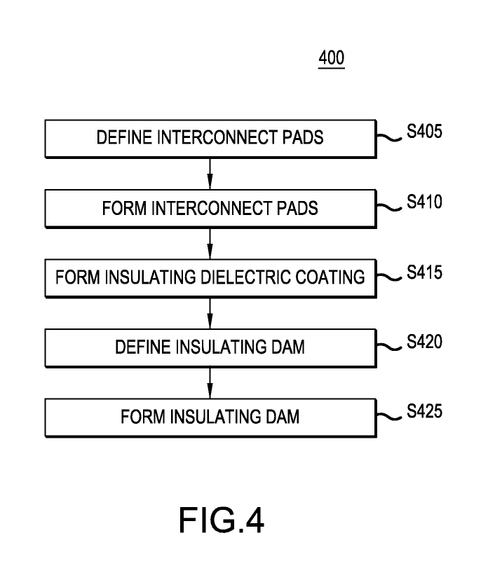

FIG. 4 is a flowchart illustrating a method 400 of manufacturing a PCB comprising a solder mask and surface pads having substantially co-planar upper surfaces, according to a representative embodiment. Method 400 can be used to form PCB 200 or 300, for instance. In the description of method 400, it is assumed that a conductive layer has already been attached to a non-conductive base layer, e.g., as shown in FIG. 3A. Accordingly, the described steps occur after the steps for attaching the conductive layer to the non-conductive layer.

Referring to FIG. 4, method 400 comprises defining interconnect pads for the PCB (S405). This can be performed, for instance, by depositing and patterning a layer of dry film as illustrated in FIG. 3A. Method 400 further comprises forming interconnect pads such as the surface pads illustrated in FIG. 3B (S410). The formation of the interconnect pads may comprise, for instance, etching the conductive layer using the patterned dry film as an etching mask. Method 400 still further comprises forming an insulating dielectric coating over the interconnect pads, as illustrated, for instance, in FIG. 3C (S415), and then defining an insulating dam between adjacent interconnect pads by forming an etching mask on the insulating dielectric coating (S420). Such an etching mask may be, for instance, a photomask used to perform photolithography on the insulating dielectric coating. Finally, method 400 comprises forming the insulating dam between the adjacent interconnect pads by etching the insulating dielectric coating (S425). The insulating dam may take the form of the portion of solder mask 315 in the trench, as shown in FIG. 3D.

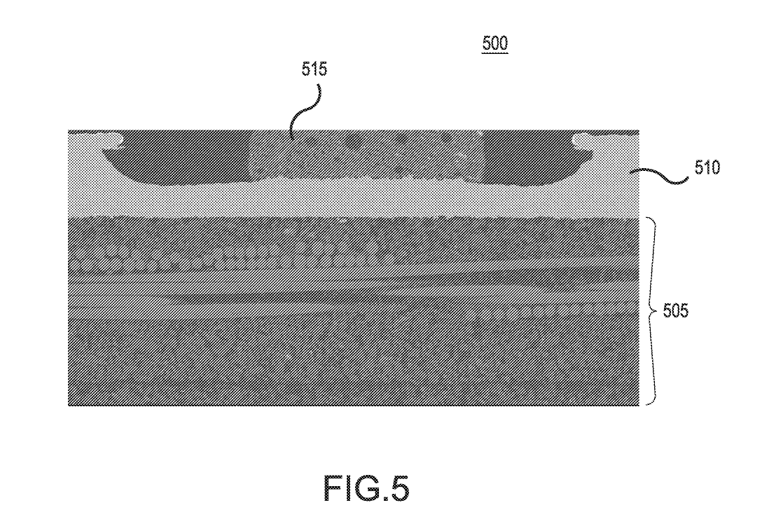

FIG. 5 is a scanning electron microscope (SEM) image of a PCB 500 comprising a solder mask and surface pads having substantially co-planar upper surfaces, according to a representative embodiment.

Referring to FIG. 5, PCB 500 comprises a base layer 505 formed of pre-preg, a copper interconnect 510 comprising two surface pads separated by a trench, and a solder mask or insulating dam 515 formed in the trench between the two surface pads and configured to electrically isolate the surface pads without actually contacting either of the surface pads.

As indicated by the foregoing, the described embodiments provide PCBs in which surface pads and a solder mask are formed with substantially co-planar surfaces. The presence of these features can improve test procedures by avoiding obstruction of test probes, and it may also improve the mechanical durability of the PCBs.

While example embodiments are disclosed herein, one of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A method of forming a printed circuit board (PCB), comprising:
patterning a conductive layer to produce at least two surface pads separated by a trench;
forming an insulating dielectric coating over the surface pads and within the trench; and
patterning the insulating dielectric coating to produce a solder mask within the trench, wherein the solder mask electrically isolates the at least two surface pads and has an upper surface that is substantially co-planar with respective upper surfaces of the at least two surface pads.

2. The method of claim 1, wherein the solder mask is physically separated from respective sides of the surface pads within the trench.

3. The method of claim 1, wherein the insulating dielectric coating comprises liquid film resist.

4. The method of claim 1, wherein the insulating dielectric coating comprises dry film resist.

5. The method of claim 2, wherein the solder mask does not touch the surface pads.

6. The method of claim 1, wherein the conductive layer is formed of copper.

7. The method of claim 1, wherein the surface pads form test probe contacts of the PCB.

8. The method of claim 1, wherein patterning the conductive layer comprises:
forming an etching mask by depositing dry film resist on the metal layer and patterning the dry film resist; and
etching the conductive layer using the etching mask.

9. The method of claim 1, wherein patterning the insulating dielectric coating comprises forming an etching mask defining the solder mask; and
etching the insulating dielectric coating using the etching mask to produce the solder mask.

10. The method of claim 1, further comprising:
before forming the insulating dielectric coating over the surface pads and within the trench, performing a cleaning process and an adhesion promotion process on the surface pads.

11. The method of claim 1, further comprising planarizing the surface pads and the solder mask to produce the substantially co-planar upper surfaces.

12. A printed circuit board (PCB), comprising:
a non-conductive base layer;
a conductive interconnect disposed on the non-conductive base layer and comprising at least two surface pads separated by a trench; and
a insulating dam disposed in the trench, wherein the insulating dam electrically isolates the at least two surface pads and has an upper surface that is substantially co-planar with respective upper surfaces of the at least two surface pads.

13. The PCB of claim 12, wherein the insulating dam is part of a solder mask disposed on the conductive interconnect.

14. The PCB of claim 12, wherein the at least two surface pads are formed of gold on copper.

15. The PCB of claim 12, wherein the at least two surface pads are formed of gold on nickel on copper.

16. The PCB of claim 12, wherein the at least two surface pads are formed of copper.

17. The PCB of claim 12, wherein the insulating dam is formed of liquid film resist.

18. The PCB of claim 12, wherein the insulating dam is formed of dry film resist.

19. The PCB of claim 12, wherein PCB is a multi-layer PCB and the surface pads are exposed through an external layer of the multi-layer PCB.

20. The PCB of claim 12, wherein the surface pads are test pads of the PCB.

21. The PCB of claim 12, wherein the surface pads form part of a connection interface for a land grid array (LGA) package.
